(19) United States
(12) Patent Application Publication
(10) Pub. No.: US 2005/0056958 A1
(43) Pub. Date: Mar. 17, 2005

(54) Forming homogeneous mixtures of organic materials for physical vapor deposition using dry mixing

(75) Inventors: Syamal K. Ghosh, Rochester, NY (US); Donn B. Carlton, Hamlin, NY (US); Tukaram K. Hatwar, Penfield, NY (US)

Correspondence Address: Thomas H. Close;Patent Legal Staff, Eastman Kodak Company, 343 State Street, Rochester, NY, 14650-2201, US

(73) Assignee: Eastman Kodak Company

(21) Appl. No.: 10/663,578

(22) Filed: Sep. 16, 2003

(51) Int. Cl. B29B 7/02; B29B 9/00; B29B 7/82; B29B 7/84

(52) U.S. Cl. 264/85; 264/349; 264/102; 264/122; 425/6

(57) ABSTRACT

Powdered organic material s are mixed to form a homogeneous mixture, which includes, at least one dopant component and one host component, to form a pellet for use in thermal physical vapor deposition to produce an organic layer on a substrate for use in an organic light-emitting device. The method of mixing includes, combining organic materials in a powder form and placing the powder organic materials in a container, heating the container in a range of temperatures from 40 to 100° C. for 30 to 100 minutes while purging the atmosphere in the container to a reduced pressure in a range from 10⁻¹ to 10⁻³ Torr to remove moisture. Filling the container with an inert atmosphere, mixing the powder organic materials in the inert atmosphere to form a homogeneous mixture of powder organic materials, and compacting the homogenous mixture of powder organic materials to form a pellet.

### CROSS REFERENCE TO RELATED APPLICATIONS

Reference is made to commonly assigned U.S. patent application Ser. No. 09/898,369 filed Jul. 3, 2001 entitled “Method of Handling Organic Material in Making An Organic Light-Emitting Device” by Van Slyke et al.; U.S. patent application Ser. No. 10/073,690 filed Feb. 11, 2002, entitled “Using Organic Materials in Making An Organic Light-Emitting Device” by Ghosh et al., U.S. patent application Ser. No. 10/195,947 filed Jul. 16, 2002, entitled “Compacting Moisture-Sensitive Organic Material in Making An Organic Light-Emitting Device” by Ghosh et al., U.S. patent application Ser. No. 10/226,600 filed Aug. 23, 2002, entitled “Solid Compacted Pellet of Organic Material for Vacuum Deposition of OLED displays and Method of Making Same” by Ghosh et al., and U.S. patent application Ser. No. 10/348,118 filed Jan. 17, 2003, entitled “Using Compacted Organic Materials In Making White Light-emitting OLEDS” by Ghosh et al., U.S. patent application Ser. No.______ filed concurrently herewith, entitled “Forming Homogeneous Mixtures of Organic Materials For Physical Vapor Deposition Using a Solvent” by Ghosh et al, U.S. patent application Ser. No.______ filed concurrently herewith, entitled “Forming Homogeneous Mixtures of Organic Materials For Physical Vapor Deposition Using Melting” by Ghosh et al, and U.S. patent application Ser. No.______ filed concurrently herewith, entitled “Forming Homogeneous Mixtures of Organic Materials For Physical Vapor Deposition Using Wet Mixing” by Ghosh et al, the teachings of which are incorporated herein.

### FIELD OF THE INVENTION

The present invention relates to making homogeneous mixtures of two or more powder organic material components for use in making an organic layer by physical vapor deposition on a substrate, which will form a part of an OLED display.

### BACKGROUND OF THE INVENTION

An organic light-emitting diode (OLED), also referred to as an organic electroluminescent device, can be constructed by sandwiching two or more organic layers between first and second electrodes.

Organic materials, thickness of vapor-deposited organic layers, and layer configurations, useful in constructing an organic light-emitting device are described for example, in commonly assigned U.S. Pat. Nos. 4,356,429; 4,539,507; 4,720,432; and 4,769,292, the disclosures of which are herein incorporated by reference.

Organic materials useful in making OLED displays, for example organic hole-transporting materials, organic light-emitting materials with an organic dopant, and organic electron-transporting materials can have relatively complex molecular structures with relatively weak molecular bonding forces, so care must be taken to avoid decomposition of the organic material during physical vapor deposition.

The aforementioned organic materials are synthesized to a relatively high degree of purity, and are provided in the form of powders, flakes, or granules. Such powders or flakes have been used heretofore for placement into a physical vapor deposition source wherein heat is applied for forming a vapor by sublimation or vaporization of the powder organic materials, the vapor condensing on a substrate to provide an organic layer thereon. In order to form a layer having more than one organic component, such as a host and a dopant component, it is desirable to co-evaporate simultaneously from two adjacent sources so that the organic components are mixed in the vapor-state prior to forming a layer on a substrate.

The co-evaporation process has several disadvantages which include (a) the vapor deposition chamber must be large to accommodate the evaporation sources for both the dopant and host component organic materials; (b) the large chambers necessary to complete co-evaporation are costly; (c) the larger the chamber, the more time that is required to reduce the pressure of the chamber prior to vaporization; and (d) each evaporation source containing a host or dopant component material must be vaporized by an independent power source, thereby increasing the cost of the co-evaporation process.

The rate of vaporization of each individual deposition source is crucial because that determines the chemical composition of the deposited organic layer on the substrate. In other words, the deposition rate determines the amount of vapor deposited on a substrate for a given length of time. Since the weight percentage of the dopant component in organic layers is lower than that of the host component, it is imperative that the deposition rate for the dopant component be adjusted accordingly. If the rate of vaporization of individual sources is not precisely controlled, the chemical composition of the vapor deposited on the substrate will be different from what is required to form a highly efficient OLED display.

Several problems associated with co-evaporation of powder organic materials, flakes or granules have also been discovered. Such problems include:
(i) powders, flakes, or granules are difficult to handle because they can acquire electrostatic charges via a process referred to as triboelectric charging;
(ii) powders, flakes, or granules of organic materials generally have a relatively low physical density (expressed in terms of weight per unit volume) in an approximate range from 0.05 to 0.2 g/cm³, compared to a physical density of an idealized solid organic material of approximately 1 g/cm³;
(iii) powders, flakes, or granules of organic materials have an undesirably low thermal conductivity, particularly when placed in a physical vapor deposition source which is disposed in a chamber evacuated to pressures as low as 10⁻⁶ Torr. Consequently, powder particles, flakes, or granules are heated only by radiative heating from a heated source, and by conductive heating of particles or flakes directly in contact with heated surfaces of the source. Powder particles, flakes, or granules which are not in contact with heated surfaces of the source are not effectively heated by conductive heating due to a relatively low particle-to-particle contact area; and
(iv) powders, flakes, or granules typically have a high ratio of surface area/volume and a correspondingly high propensity to entrap air and moisture between particles under ambient conditions. Consequently, a charge of organic powders, flakes, or granules loaded into a physical vapor deposition source, which is disposed in a chamber must be thoroughly outgased by preheating the source once the chamber has been evacuated to a reduced pressure.

If outgasing is omitted or is incomplete, particulate can be ejected from the evaporation source during the physical vapor deposition process. An OLED, having multiple organic layers, can become functionally inoperative if such layers include particles or particulates. Compaction of powder organic materials for making OLED displays using a physical vapor deposition method is described by Van Slyke et al. in a commonly assigned U.S. Patent Application No. Publication 2003/0008071 A1, the disclosure of which is incorporated herein by reference.

Each one, or a combination, of the aforementioned aspects of organic powders, flakes, or granules can lead to nonuniform heating of such organic materials in physical vapor deposition sources with attendant spatially nonuniform vaporization of organic material, which can, result in potentially nonuniform vapor-deposited organic layers formed on a structure.

### SUMMARY OF THE INVENTION

It is an object of the present invention to provide a method and mechanism for mixing of powder organic materials adaptable for making on organic layer on a structure, which will form a part of an OLED display.

It is another object of the present invention to provide a homogeneous mixture of powder organic materials including at least one host and at least one dopant adaptable for making an organic layer on a structure, which will form a part of an OLED display.

These objects are achieved by a method for forming a homogeneous mixture of powder organic materials including at least one dopant component and one host component to form a pellet for use in thermal physical vapor deposition to produce an organic layer on a substrate for use in an organic light-emitting device, comprising:
a) combining organic materials in a powder form, such materials including at least one dopant component and one host component and placing the powder organic materials in a container;
b) heating the container having the powder organic materials in a range of temperatures from 40 to 100° C. for 30 to 100 minutes while purging the atmosphere in the container so that the atmosphere has a reduced pressure in a range from 10⁻¹ to 10⁻³ Torr to remove moisture from the container atmosphere;
c) filling the container with an inert atmosphere;
d) mixing the powder organic materials in the inert atmosphere using a mixing mechanism to form a homogeneous mixture of powder organic materials; and
e) compacting the homogenous mixture of powder organic materials to form a pellet suitable for thermal physical vaporization to produce an organic layer on a substrate for use in an organic light-emitting device.

These objects are further achieved by an apparatus for mixing powder organic materials, including at least one dopant component and one host component to provide a homogeneous mixture for use in forming a pellet for thermal physical vapor deposition to produce an organic layer on a substrate for use in an organic light-emitting device, comprising:
a) a container, containing a mixture of powder organic materials including at least one dopant component and one host component;
b) a mixing mechanism disposed in the container for mixing the mixture of powder organic material;
c) means for removing moisture from the container
d) means for providing an inert atmosphere into the container;
e) first periodic motion means for moving the mixing mechanism with a first periodic motion; and
f) second periodic motion means for moving the container with a second periodic motion to provide a homogenous mixture for use in forming a pellet for thermal physical vapor deposition producing an organic layer on a substrate for use in an organic light-emitting device.

A feature of the present invention is that the above method of dry mixing is very fast and cost effective.

Another feature of the dry mixing is that no chemicals are added to potentially contaminate the organic mixture.

Another feature of the present invention is an effective way to provide homogeneous mixtures of organic materials that can be vaporized from a single source thereby avoiding the problems associated with co-evaporation of single component materials.

Another feature of the present invention is that compacted pellets can be formed from homogenous mixtures of organic materials thereby avoiding the problems associated with vaporization of organic powders, flakes or granules.

Another feature of the present invention is that a compacted pellet formed from a homogeneous mixture of organic materials can be evaporated for a longer duration from a single evaporation source rather than co-evaporation from a multiple evaporation sources as in single component materials.

### BRIEF DESCRIPTION OF THE DRAWINGS

FIG. 1 shows a schematic flowchart of mixing powder organic materials in a dry state using either ultrasonic or a propeller mixer; and

FIG. 2 shows cross-sectional view of an apparatus for mixing powder organic materials.

The term “powder” is used herein to denote a quantity of individual particles, which can be flakes, granules, or mixtures of varied particles and shapes comprising single or plurality of molecular species.

### DETAILED DESCRIPTION OF THE INVENTION

The organic layers of an OLED display include an organic or organo-metallic material that produces light, known as electroluminescence (EL), as a result of electron-hole recombination in the layer. Hereinafter, the term “organic” will be taken to include both purely organic as well as organo-metallic materials.

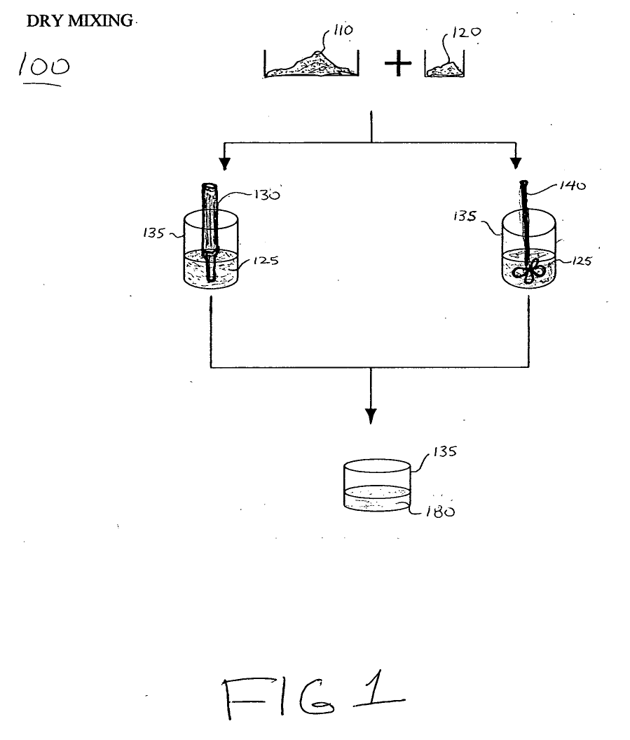

Turning to FIG. 1 now, a schematic flow chart shows a dry mixing process 100. The dry mixing process 100 involves combining organic materials in a powder form having a host component organic powder 110 and a dopant component organic powder 120 to form a mixture of powder organic materials 125, and placing the mixture in a container 135. Depending upon the application and functionality of the mixture of powder organic materials 125, the dopant component 120 may vary from 0.1 to 20% by weight of the total mixture weight. Organic powders used as a host component 110 in the present invention are Alq3, NPB and TBADN. Examples of some organic dopant components 120 used in this invention are DCJTP, Rubrene, OP31, DPQA and DBzR.

The container 135, containing the mixture of powder organic materials 125 is placed in a vacuum furnace. The container 135, having the powder organic materials 125, is heated in a range of temperatures from 40 to 100° C. for 30 to 100 minutes while purging the atmosphere to a reduced pressure in a range of 10⁻¹ to 10⁻³ Torr in order to reduce the moisture content of the powder organic materials 125. It is important to remove the moisture from the powder organic materials 125 in order to facilitate mixing and maintain a consistent chemical composition. The mixture of powder organic materials 125 can be stored in a reduced pressure atmosphere of 10⁻¹ to 10⁻³ Torr, until mixing.

Mixing is typically accomplished by propeller mixing, wherein a propeller or turbine blade 140 is used to mix the mixture of powder organic materials 125 to form the homogeneous mixture of powder organic materials 180. Alternatively, ultrasonic mixing can be completed using an ultrasonic horn 130. After the moisture has been reduced by evaporation and heating, a mixing mechanism, typically a propeller or turbine blade 140 is placed in the container 135. The container 135 is sealed using a container cover (not shown) having at least one sealable opening for the propeller or turbine blade 140 to pass through, while preserving an air-tight seal.

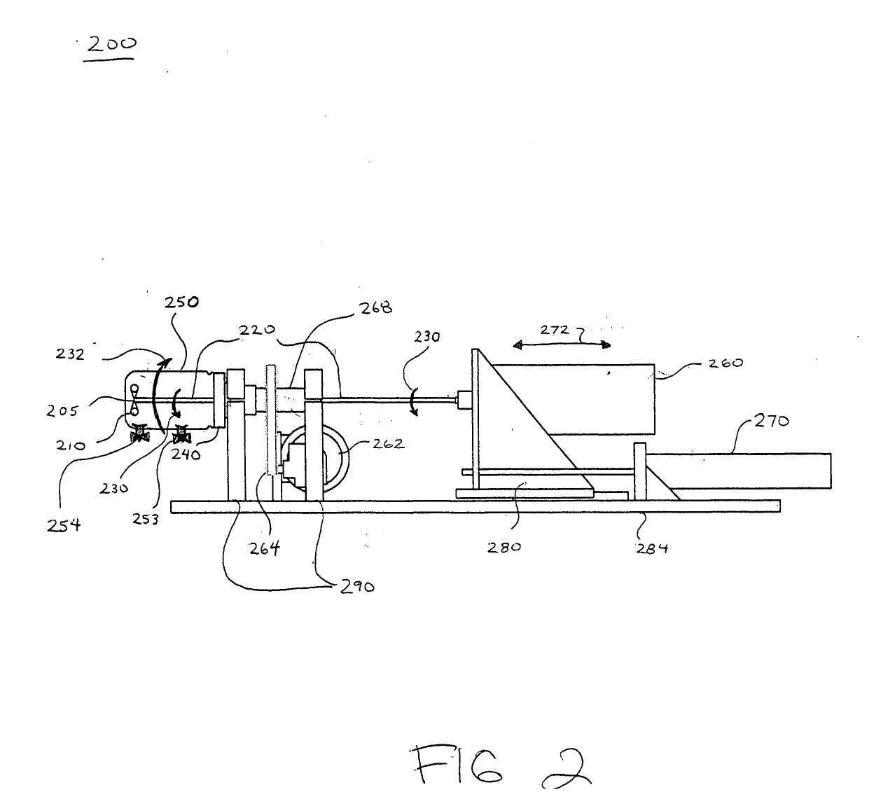

After sealing the container 135, the ambient atmosphere is evacuated from the container 135 and the container 135 is filled with an inert atmosphere such as nitrogen gas, argon gas or a mixture thereof. The container 135 is equipped with an intake pressure control device 253 (see FIG. 2) for controlling the flow of gas into the container 135 and an outtake pressure control device 254 (see FIG. 2) for controlling the evacuation of gas from the container 135. After the container 135 is sealed and an inert atmosphere is provided in the container, the mixture of powder organic materials 125 are mixed to form the homogeneous mixture of powder organic materials 180. The apparatus for mixing the powder organic materials is described in the detailed description of FIG. 2.

After the homogeneous mixture of powder organic materials 180 is obtained it is removed from the container 135 and compacted to form a pellet suitable for physical vapor deposition to produce an organic layer on a substrate for use in an organic light-emitting device. The pellets are compacted in a range of pressures between 3,000 and 20,000 pounds per square inch.

Turning to FIG. 2, a cross-sectional view of an apparatus for mixing powder organic materials 200 is shown. The apparatus includes a container 250 for containing the mixture of powder organic materials during mixing and a mixing mechanism 205 disposed in the container 250 for mixing the mixture of powder organic material. The mixing mechanism 205 is typically a propeller or turbine blade 210 attached to a first rotatable shaft 220. The propeller 210 is rotated at high speeds to mix the powder organic materials to obtain a homogeneous mixture. The container 250, preferably a transparent glass container for witnessing the mixing process, is fitted with an air-tight container cover 240. The mixing process can be monitored visually through the transparent container 250 so that an observer can determine when a homogeneous mixture of powder organic materials is obtained. The container cover 240 provides a sealed atmosphere in the container 250 and has at least one sealable opening through which the first rotatable shaft 220 can be inserted in order for the propeller or turbine blade 210 to be inserted into the container 250 to mix the powder.

The container 250 is also equipped with two pressure control devices. One intake pressure control device 253 has a flow valve and a release valve for providing an inert atmosphere in the container. An outtake pressure control device 255 has a flow valve and a release valve for removing moisture from the container. The second pressure control device is coupled to a vacuum pump (not shown) that is capable of providing a negative pressure gradient in order to purge the ambient atmosphere from the container 250, which is replaced with an inert atmosphere before mixing. The inert atmosphere is typically nitrogen gas, argon gas or a mixture thereof. After the mixing, the inert atmosphere can be purged. The inert atmosphere provides a dry atmosphere to avoid the introduction of water that may change the chemistry of any hydroscopic powder organic materials aids mixing.

A motor 260 drives the first rotatable shaft 220 in a direction of rotation 230. The first rotatable shaft rotates at a rate in a range of 20,000 to 50,000 revolutions per minute. The motor 260 is mounted on a traversing bracket 280, which in turn is fixed to a base plate 284. A pneumatic cylinder 270 moves the traversing bracket 280 in a reciprocating motion 272 so that the mixing mechanism can traverse from one end of the container 250 to the other during the mixing process. The reciprocating motion 272 is no greater than the length of the container 250. The mixing mechanism traverses in a reciprocating motion at a rate in a range of 30 to 60 cycles per minute.

A second rotatable shaft 268 is driven by an electric motor 262 via a belt and pulley arrangement 264. The electric motor 262 rotates the second rotatable shaft 268 coupled to the container 250 at a rate in a range of 10 to 60 revolutions per minute. During mixing, the second rotatable shaft 268 can be rotated in a direction of rotation 232 opposite to the direction of rotation 230 of the first rotatable shaft 220 and the mixing mechanism 210. Alternatively, the second rotatable shaft 268 can be rotated in a direction corresponding to the direction 230 of the first rotatable shaft 220. The first rotatable shaft 220 and the second rotatable shaft 268 are coupled with plain bearings (not shown), which are supported by a bearing support 290.

### WORKING EXAMPLES

### Example 1

### Blue Emission Layer

First, 2.0 grams of organic dopant powder TBP and 8.0 grams of organic host powder TBADN were placed in an airtight glass container. The container was used with the apparatus for mixing powder organic materials as described in the detailed description provided for FIG. 2. The propeller operated at approximately 25,000 revolutions per minute and mixed the powder organic materials for 5 to 7 minutes, until a homogeneous mixture of organic materials was obtained. After mixing, the air-borne particles were allowed to settle inside the container, and the container was opened and 2.0 grams of the homogenous mixture of organic materials was dispensed for compaction.

The homogeneous mixture of powder organic material was compacted into a pellet suitable for physical vapor deposition. The compacted pellet was placed in a quartz boat and the pellet was heated from the top using a Ta heater according to the prior art described by S. Van Slyke et al, SID 2002 Digest, pp. 886-889, 2002, which is incorporated herein for reference. Several OLED displays having the following structure were formed on a glass substrate coated with an indium-tin oxide anode:
Hole injection layer: CFx: Thickness=5 nm
HTL: NPB. Thickness=75 nm
EML: TBADN+2% TBP. Thickness=: 20 nm
ETL: Alq3. Thickness=35 nm
Cathode: MgAg. Thickness=200 nm

Initially, five OLED displays were made wherein the EML was formed by using a compacted pellet weighing approximately 2.0 grams and other organic layers such as a HTL and an ETL were formed using organic materials and a top heated quartz boat. Another set of five OLED displays was made after one hour of continuous evaporation. The compacted pellet was heated continuously for approximately 200 minutes until the pellet was completely consumed and a set of five OLED displays were made at intervals of 30 minutes. A shutter during the continuous deposition process protected the substrates and the shutter was opened only when emission layers were deposited to form an OLED display.

The average EL results of each set of five OLED displays are shown in Table 1. The OLED displays in group A denote the average performance of five OLED displays made at the beginning of the deposition process, OLED displays in group B denote the average performance of five displays made after 120 minutes of continuous deposition and OLED displays in group C denote the average EL performance of five OLED displays made after 180 minutes of deposition.

TABLE 1
EL results of blue OLED displays formed according to
the invention.

| | EML | OLED | Drive | Luminance | |
|---|---|---|---|---|---|
| Experiment | Composition | displays | Voltage | Yield (cd/A) | CIEx,y |
| 1 | TBADN + | A | 7.1 V | 2.51 | 0.15,0.20 |
| | 2% TBP | | | | |
| 2 | TBADN + | B | 7.0 V | 2.35 | 0.14,0.19 |
| | 2% TBP | | | | |
| 3 | TBADN + | C | 6.8 | 2.40 | 0.14,0.18 |
| | 2% TBP | | | | |

The experimental results summarized in Table 1 indicate that the EL characteristics such as drive voltage, luminance yield and color coordinates, CIEx,y of the blue emission layer formed according to the invention remained uniform throughout the entire length of the deposition process indicating that the composition of the organic materials which included 98% TBADN (host) and 2% TBP (dopant) remained unchanged.

### Example 2

### Red Emission Layer

First, 0.5 g. of organic dopant powder Rubrene, 0.15 g of another organic dopant powder DCJTB, 4.675 g of organic host powder TBADN, and 4.675 g. of another organic host powder Alq3 were placed in a glass container which was attached to the high speed propeller mixing apparatus. The high-speed propeller operated at approximately 25,000 rpm and mixed the powder organic materials for about 5 to 7 minutes until a homogeneous mixture of organic materials was obtained. Dry argon gas was purged into the container during the mixing process to make sure that Alq3 was not exposed to ambient moisture.

After mixing, the air-borne particles were allowed to settle inside the glass container, after which, the container was opened and 2.0 grams of the homogenous mixture of organic materials was dispensed for compaction. The homogeneous mixture of powder organic material was compacted into a pellet for the physical vapor deposition process. The compacted pellet was placed in a quartz boat wherein the pellet was heated from the top using a Ta heater according to the prior art described by S. VanSlyke et al, SID 2002 Digest, pp. 886-889, 2002, which is incorporated herein for reference. Several OLED displays having the following structure was formed on a glass substrate coated with an indium-tin oxide anode:
Hole injection layer: CFx. Thickness=5 nm
HTL: NPB. Thickness=75 nm
EML: Host−[TBADN+Alq3 (1:1)]/Dopant−5% Rubrene+1.5% DCJTB. Thickness=35 nm
ETL: Alq3. Thickness=35 nm
Cathode: MgAg. Thickness=200 nm.

Initially, five OLED displays were made wherein the EML was formed by using a compacted pellet weighing approximately 2.0 grams and other organic layers such as a HTL and an ETL were formed using organic materials and a top heated quartz boat. Another set of five OLED displays was made after one hour of continuous evaporation. The compacted pellet was heated continuously for approximately 200 minutes until the pellet was completely consumed and a set of five OLED displays were made at intervals of 30 minutes. A shutter during the continuous deposition process protected the substrates and the shutter was opened only when emission layers were deposited to form an OLED display.

The average EL results of each set of five OLED displays are shown in Table 1. The OLED displays in group A denote the average performance of five OLED displays made at the beginning of the deposition process, OLED displays in group B denote the average performance of five displays made after 120 minutes of continuous deposition and OLED displays in group C denote the average EL performance of five OLED displays made after 180 minutes of deposition.

TABLE 2
EL results of red OLED displays formed accfording to the
invention.

| | EML | OLED | Drive | Luminance | |
|---|---|---|---|---|---|
| Experiment | Composition | displays | Voltage | Yield (cd/A) | CIEx,y |
| 4 | TBADN + | D | 9.2 | 4.8 | 0.59,0.40 |
| | Alq3 (1:1) | | | | |
| | 5% | | | | |
| | Rubrene + | | | | |
| | 1.5% | | | | |
| | DCJTB | | | | |
| 5 | TBADN + | E | 9.0 | 4.42 | 0.60,0.40 |
| | Alq3 (1:1) | | | | |
| | 5% | | | | |
| | Rubrene + | | | | |
| | 1.5% | | | | |
| | DCJTB | | | | |
| 6 | TBADN + | F | 9.0 | 4.43 | 0.60,0.40 |
| | Alq3 (1:1) | | | | |
| | 5% | | | | |
| | Rubrene + | | | | |
| | 1.5% | | | | |
| | DCJTB | | | | |

The experimental results summarized in Table 2 indicate that the EL characteristics of the red emission layer formed according to the invention remained fairly uniform throughout the entire length of the deposition process indicating that the composition of the powder organic materials which included 1:1 TBADN: Alq3 as host which were doped with 5% Rubrene and 1.5% DCJTB remained unchanged throughout the deposition process.

The invention has been described in detail with particular reference to certain preferred embodiments thereof, but it will be understood that variations and modifications can be effected within the spirit and scope of the invention.

### PARTS LIST

100 Dry Mixing Process

110 Host Component Organic Powder

120 Dopant Component Organic Powder

125 Mixture of Powder Organic Materials

130 Ultrasonic Horn

135 Container

140 High-speed Propeller or Turbine Blade

180 Homogeneous Mixture of Powder Organic Materials

200 Apparatus for Mixing Powder Organic Materials

205 Mixing Mechanism

210 Propeller or Turbine Blade

220 First Rotatable Shaft

230 Direction of Rotation of the First Rotatable Shaft

232 Direction of Rotation of Second Rotatable Shaft

240 Container Cover

250 Container

253 Intake Pressure Control Device

254 Outtake Pressure Control Device

260 Motor

262 Electric Motor

264 Belt and Pulley Arrangement

268 Second Rotatable Shaft

270 Pneumatic Cylinder

272 Reciprocating Motion

280 Traversing Bracket

284 Base Plate

290 Bearing Support

1. A method for forming a homogeneous mixture of powder organic materials including at least one dopant component and one host component to form a pellet for use in thermal physical vapor deposition to produce an organic layer on a substrate for use in an organic light-emitting device, comprising:
a) combining organic materials in a powder form, such materials including at least one dopant component and one host component and placing the powder organic materials in a container;
b) heating the container having the powder organic materials in a range of temperatures from 40 to 100° C. for 30 to 100 minutes while purging the atmosphere in the container so that the atmosphere has a reduced pressure in a range from 10⁻¹ to 10⁻³ Torr to remove moisture from the container atmosphere;
c) filling the container with an inert atmosphere;
d) mixing the powder organic materials in the inert atmosphere using a mixing mechanism to form a homogeneous mixture of powder organic materials; and
e) compacting the homogenous mixture of powder organic materials to form a pellet suitable for thermal physical vaporization to produce an organic layer on a substrate for use in an organic light-emitting device.

2. The method of claim 1 wherein the mixing mechanism includes a propeller or a turbine blade.

3. The method of claim 1 wherein the amount of dopant component varies between 0.1 and 20% by weight of the total weight of the mixture.

4. The method of claim 1 wherein the inert atmosphere includes nitrogen gas, argon gas, or a mixture thereof.

5. The method of claim 1 wherein the homogeneous mixture of powder organic materials is compacted at a pressure in a range of 3,000 to 20,000 pounds per square inch.

6. The method of claim 1 further including storing the container before mixing in a reduced pressure atmosphere in a range from 10⁻¹ to 10⁻³ Torr.

7. The method of claim 1 wherein mixing using the mixing mechanism includes rotating the mixing mechanism in a first periodic motion at a rate in a range of 20,000 to 50,000 revolutions per minute.

8. The method of claim 1 wherein mixing includes rotating the container in a second periodic motion at a rate in a range of 10 to 60 revolutions per minute.

9. The method of claim 1 wherein mixing using the mixing mechanism includes reciprocating the mixing mechanism in a third periodic motion at a rate in a range of 30 to 60 cycles per minute.

10. The method of claim 9 wherein the third periodic motion of the mixing mechanism includes traversing the length inside of the sealed container by means of a pneumatic cylinder and a traversing bracket.

11. The method of claim 8 wherein moving the mixing mechanism in a second periodic motion includes rotating or turning the container.

12. The method of claim 7 wherein the mixing mechanism is moved in a first periodic direction opposite the second periodic direction of the container.

13. The method of claim 7 wherein the mixing mechanism is moved in a first periodic direction corresponding to the second periodic direction of the container.

14. Apparatus for mixing powder organic materials, including at least one dopant component and one host component to provide a homogeneous mixture for use in forming a pellet for thermal physical vapor deposition to produce an organic layer on a substrate for use in an organic light-emitting device, comprising:
a) a container, containing a mixture of powder organic materials including at least one dopant component and one host component;
b) a mixing mechanism disposed in the container for mixing the mixture of powder organic material;
c) means for removing moisture from the container
d) means for providing an inert atmosphere into the container;
e) first periodic motion means for moving the mixing mechanism with a first periodic motion; and
f) second periodic motion means for moving the container with a second periodic motion to provide a homogenous mixture for use in forming a pellet for thermal physical vapor deposition producing an organic layer on a substrate for use in an organic light-emitting device.

15. The apparatus of claim 14 wherein the mixing mechanism includes a propeller or turbine blade.

16. The apparatus of claim 14 wherein the mixing mechanism includes a shaft connected to the propeller or turbine blade.

17. The apparatus of claim 14 wherein the first periodic motion means of moving the mixing mechanism includes a first rotatable shaft for rotating the mixing mechanism in a first periodic motion at a rate in a range of 20,000 to 50,000 revolutions per minute.

18. The apparatus of claim 14 wherein second periodic motion means of moving the container includes a second rotatable shaft coupled to the container for rotating the container in a second periodic motion at a rate in a range of 10 to 60 revolutions per minute

19. The apparatus of claim 14 further including reciprocating means for moving the mixing mechanism in a reciprocating motion at a rate in a range of 30 to 60 cycles per minute.

20. The apparatus of claim 19 wherein the reciprocating means includes a pneumatic cylinder and a traversing bracket.

21. The apparatus of claim 14 wherein the means for providing an inert atmosphere includes an intake pressure control device having a flow valve and a release valve.

22. The apparatus of claim 21 wherein the inert atmosphere includes nitrogen gas, argon gas or a mixture thereof.

23. The apparatus of claim 14 wherein the mixing mechanism is moved in a first periodic motion corresponding to the second periodic motion of the container.

24. The apparatus of claim 14 wherein the mixing mechanism is moved in a first periodic motion opposite to the second periodic motion of the container.

25. The apparatus of claim 14 wherein the means for removing moisture from the container includes an outtake pressure control device having a flow valve and a release valve.

26. The apparatus of claim 25 wherein the outtake pressure control device is connected to a vacuum pump.
